(19) United States
(12) Patent Application Publication
(10) Pub. No.: US 2008/0024226 A1
(43) Pub. Date: Jan. 31, 2008

(54) Inverting amplifier

(75) Inventors: Tatsuya Suzuki, Saitama (JP); Yasuhiro Kaneta, Gunma (JP)

Correspondence Address: MORRISON & FOERSTER LLP, 1650 TYSONS BOULEVARD, SUITE 400, MCLEAN, VA, 22102, US

(73) Assignees: SANYO ELECTRIC CO., LTD., Moriguchi-Shi (JP); Sanyo Semiconductor Co., Ltd., Gunma (JP)

(21) Appl. No.: 11/878,439

(22) Filed: Jul. 24, 2007

(30) Foreign Application Priority Data
Jul. 25, 2006 (JP) 2006-201462

(51) Int. Cl. H03G 3/00

(52) U.S. Cl. 330/282

(57) ABSTRACT

A conventional inverting amplifier has a problem that an oscillation may be induced depending on a structure of an internal amplifier. This invention offers an inverting amplifier having a multi-stage amplifier that is provided with a first transistor that amplifies an input signal, a second transistor that amplifies an output signal of the first transistor, a third transistor that amplifies an output signal of the second transistor and an internal feedback resistor that feeds back an output signal of the third transistor to an output node of the first transistor. With the structure described above, a required gain can be set without inducing oscillation, because a gain of the multi-stage amplifier composed of three-stage transistors can be reduced.

### CROSS-REFERENCE OF THE INVENTION

This application claims priority from Japanese Patent Application No. 2006-201462, the content of which is incorporated herein by reference in its entirety.

### BACKGROUND OF THE INVENTION

1. Field of the Invention

This invention relates to an inverting amplifier that amplifies small signals, specifically to an inverting amplifier that has low distortion and adjustable gain and does not induce oscillation.

2. Description of the Related Art

The inverting amplifier has been known. FIG. 2 shows an example of the inverting amplifier. As shown in FIG. 2, an input signal from an input terminal 1 is applied to an inverting input terminal (−) of an operational amplifier 3 through a resistor 2. An output signal from an output terminal 4 of the operational amplifier 3 is fed back to the inverting input terminal (−) of the operational amplifier 3 through a resistor 5.

Being amplified by the operational amplifier 3, a mixed signal of the input signal and the fed-back signal is generated at the output terminal 4.

Therefore, with the inverting amplifier shown in FIG. 2, the input signal from the input terminal 1 is amplified and outputted to the output terminal 4. A gain of the inverting amplifier shown in FIG. 2 is determined by the resistor 2, the resistor 5 and an open loop gain of the operational amplifier 3.

The prior art is disclosed in Japanese Patent Application Publication Nos. 2000-252771 and H08-148944.

With the operational amplifier 3 shown in FIG. 2, however, there is a problem that an oscillation may be induced depending on a structure of an internal amplifier. A multi-stage amplifier using a plurality of common source transistors may be used in the operational amplifier 3.

In order to reduce a distortion of the output signal of the inverting amplifier shown in FIG. 2, it is preferable to set a high gain for the multi-stage amplifier in the operational amplifier 3.

When the high gain is set for the multi-stage amplifier in the operational amplifier 3, however, there is a worry of oscillation resulting from an influence of a parasitic capacitance of transistors that constitute the multi-stage amplifier. When a low gain is set for the multi-stage amplifier in the operational amplifier 3 to avoid the oscillation in consideration of the above, there arises a problem of the distortion described above because a gain of the multi-stage amplifier as a whole is reduced. For example, when the multi-stage amplifier is formed of three stages of transistors, the gain becomes so high to cause the worry of oscillation.

Forming the multi-stage amplifier with two stages of transistors to cope with the situation results in a positive feedback and an oscillator itself can not be formed. When the multi-stage amplifier is formed of a single stage transistor, enough gain is not obtained.

FIGS. 3A and 3B show a correlation between the gain and a signal frequency and a correlation between a phase and the signal frequency in a negative feedback loop when the multi-stage amplifier is provided in the operational amplifier 3 shown in FIG. 2. FIG. 3A shows the correlation between the gain and the signal frequency. As shown in FIG. 3A, the gain is as high as 100 dB when the signal frequency is low, since the parasitic capacitance of the transistors that constitute the multi-stage amplifier exerts no influence on the gain.

Also as shown in FIG. 3A, since the parasitic capacitance of the transistors that constitute the multi-stage amplifier becomes to be influential, or becomes visible for higher signal frequency, the gain begins to drop based on its LPF characteristics.

The reduction in the gain begins at a point C₁R₁ at first and then further reduction in the gain begins at a point C₂R₂, as shown in FIG. 3A. The phase varies by 90 degrees at the point C₁R₁ and then further varies by 90 degrees at the point C₂R₂, as shown in FIG. 3B.

FIG. 3B shows that the negative feedback is normal as the phase is 180 degrees up to the point C₁R₁. However, the feedback becomes 90 degrees beyond the point C₁R₁. The phase further varies to 0 degree at the point C₂R₂.

Then, at a signal frequency indicated by a two-dot chain line in FIGS. 3A and 3B, the feedback becomes positive feedback and the gain becomes larger than 0 dB as clearly seen from FIG. 3A. As a result, the circuit with the characteristics shown in FIGS. 3A and 3B ends up in oscillation at a signal frequency f₃, since it satisfies conditions of oscillation, that are the positive feedback and the gain equal to or larger than 0 dB.

### SUMMARY OF THE INVENTION

This invention is directed to solve the problems addressed above, and offers an inverting amplifier having a multi-stage amplifier that is provided with a first transistor that amplifies an input signal, a second transistor that amplifies an output signal of the first transistor, a third transistor that amplifies an output signal of the second transistor and an internal feedback resistor that feeds back an output signal of the third transistor to an output node of the first transistor.

With the structure described above, a required gain can be set without inducing oscillation, because a gain of the multi-stage amplifier composed of three-stage transistors can be reduced.

This invention also offers an inverting amplifier having a multi-stage amplifier that is provided with a first transistor that amplifies an input signal, a second transistor that amplifies an output signal of the first transistor, a third transistor that amplifies an output signal of the second transistor, a fourth transistor that amplifies an output signal of the third transistor, a fifth transistor that amplifies an output signal of the fourth transistor and an internal feedback resistor that feeds back an output signal of the fifth transistor to an output node of the first transistor.

With the structure described above, a required gain can be set without inducing oscillation, because a gain of the multi-stage amplifier composed of five-stage transistors can be reduced.

This invention also offers an inverting amplifier having a first resistor connected between an input terminal and an inverting input terminal, a second resistor connected between an output terminal and the inverting input terminal and a multi-stage amplifier provided with a first transistor that amplifies an input signal from the inverting input terminal, a second transistor that amplifies an output signal of the first transistor, a third transistor that amplifies an output signal of the second transistor and an internal feedback resistor that feeds back an output signal of the third transistor to an output node of the first transistor.

With the structure described above, a required gain can be set without inducing oscillation, because a gain of an operational amplifier as a whole can be reduced by the first resistor, the second resistor and a gain of the multi-stage operation amplifier.

### BRIEF DESCRIPTION OF THE DRAWINGS

FIG. 1 shows an inverting amplifier according to a first embodiment of this invention.

FIG. 2 shows a conventional inverting amplifier.

FIGS. 3A and 3B show correlation between a gain and a signal frequency and a correlation between a phase and the signal frequency, respectively, of a conventional multi-stage amplifier.

FIGS. 4A and 4B show correlation between a gain and a signal frequency and a correlation between a phase and the signal frequency, respectively, of a multi-stage amplifier according to the first embodiment of this invention.

FIG. 5 shows the multi-stage amplifier according to the first embodiment of this invention.

FIG. 6 shows a transfer function of the multi-stage amplifier shown in FIG. 5.

FIG. 7 shows an inverting amplifier according to a second embodiment of this invention.

### DETAILED DESCRIPTION OF THE INVENTION

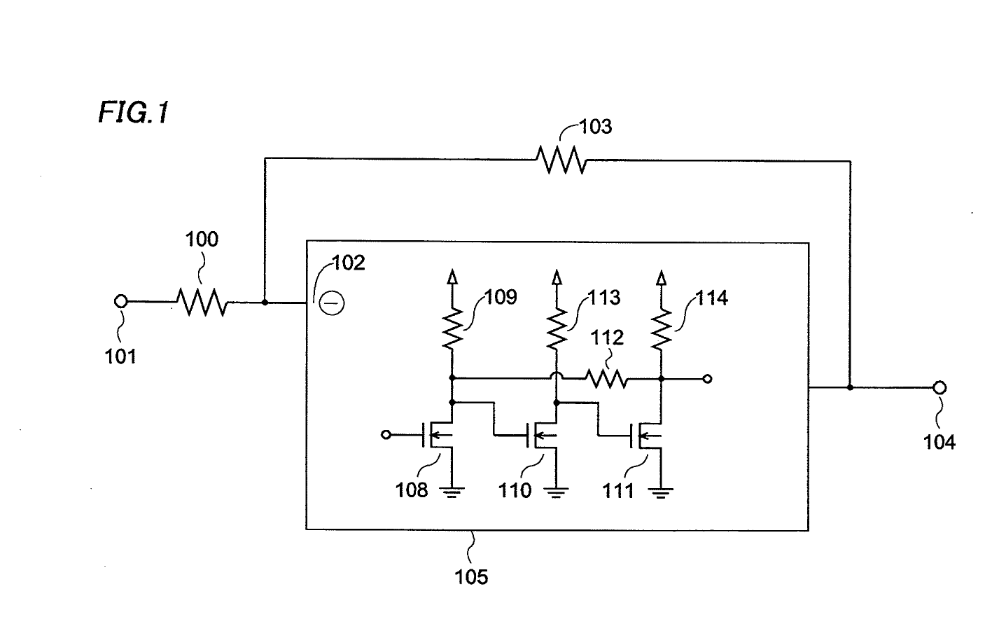

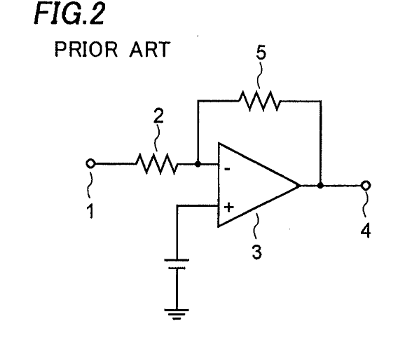

A first embodiment of this invention is described in detail, referring to the drawings. FIG. 1 shows an inverting amplifier according to the first embodiment.

FIG. 1 shows a first resistor 100 connected between an input terminal 101 and an inverting input terminal 102, a second resistor 103 connected between an output terminal 104 and the inverting input terminal 102, an operational amplifier 105, a first transistor 108 that has a gate to which an input signal from the inverting input terminal 102 is applied, a source which is grounded and a drain to which a resistor 109 is connected and amplifies the input signal, a second transistor 110 that amplifies an output signal of the first transistor 108, a third transistor 111 that amplifies an output signal of the second transistor 110 and an internal feedback resistor 112 that feeds back an output signal of the third transistor 111 to an output node of the first transistor 108.

As shown in FIG. 1, an input signal from the input terminal 101 is applied to the inverting input terminal (−) 102 of the operational amplifier 105 through the first resistor 100. The output signal from the output terminal 104 of the operational amplifier 105 is fed back to the inverting input terminal (−) 102 of the operational amplifier 105 through the second resistor 103.

Being amplified by the operational amplifier 105, a mixed signal of the input signal and the fed-back signal is generated at the output terminal 104.

Here, an open loop gain of the operational amplifier 105 itself is determined by a total gain of a multi-stage amplifier composed of the first transistor 108, the second transistor 110 and the third transistor 111. The multi-stage amplifier includes the internal feedback resistor 112 interposed between a drain of the third transistor 111 and the drain of the first transistor 108. The internal feedback resistor 112 serves to reduce (adjust) the total gain of the multi-stage amplifier to a desired value.

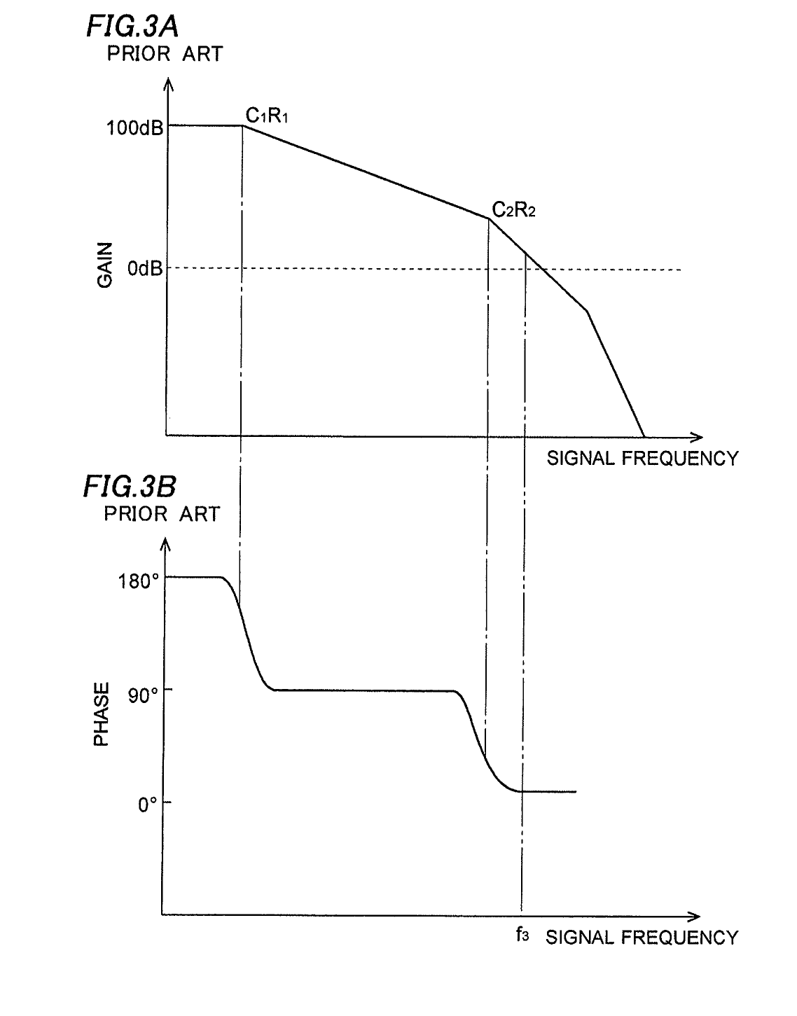

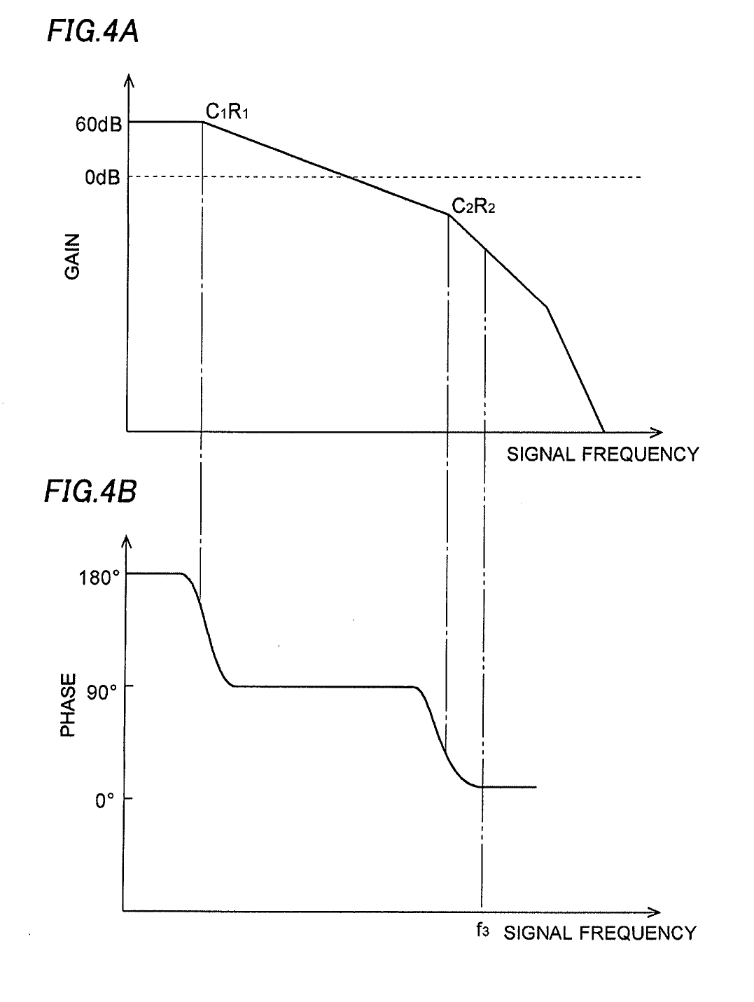

That is, a situation such as shown in FIGS. 3A and 3B at the signal frequency f₃ when the high gain is generated with the three-stage structure made of the first transistor 108, the second transistor 110 and the third transistor 111 does not take place. A corresponding situation in the first embodiment is shown in FIGS. 4A and 4B. A position of 0 dB is higher in FIG. 4A than in FIG. 3A. As a result, the oscillation is not induced around the signal frequency f₃, because the gain is less than 0 dB although the positive feedback takes place at the signal frequency f₃.

Next, how the internal feedback resistor 112 serves to reduce the total gain of the multi-stage amplifier will be explained.

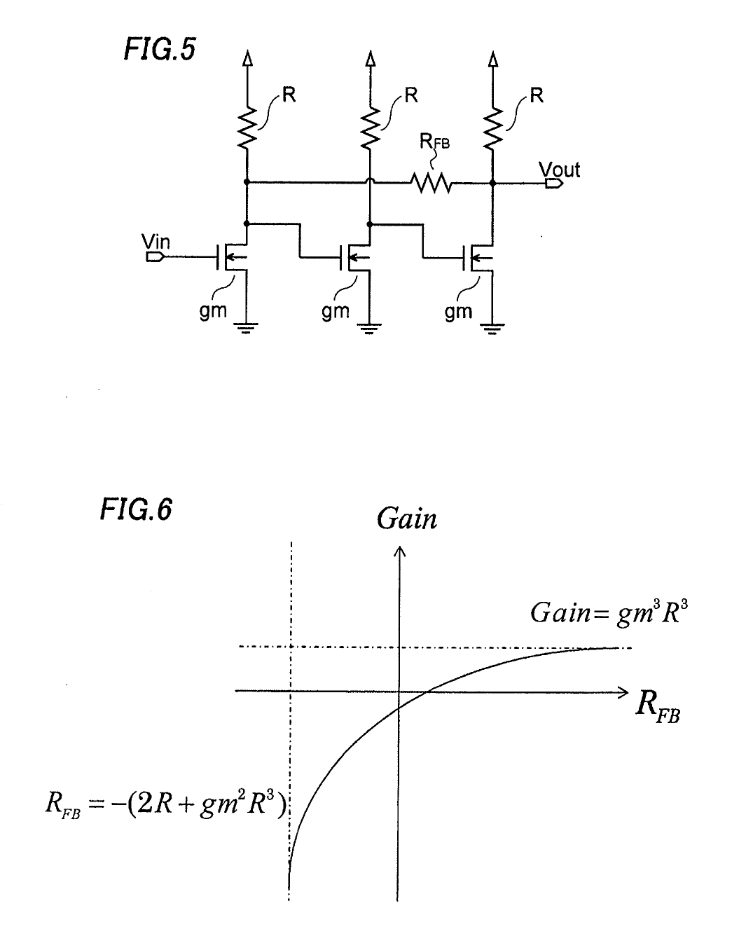

FIG. 5 shows the multi-stage amplifier composed of the first transistor 108, the second transistor 110 and the third transistor 111. It is assumed that a mutual conductance of each of the first transistor 108, the second transistor 110 and the third transistor 111 is gm. It is also assumed that a resistor 113 connected with a drain of the second transistor 110 and a resistor 114 connected with the drain of the third transistor 111 have the same resistance as a resistance R of the resistor 109. And the internal feedback resistor 112 has a resistance R_{FB}. Then, a transfer function (gain) of the multi-stage amplifier shown in FIG. 5 is represented by Equation 1.

$$Gain = \frac{Vout}{Vin} = \frac{{gm}^{3} {R}^{3} {R}_{FB} - {gmR}^{2}}{{R}_{FB} + 2 R + {gm}^{2} {R}^{3}} \qquad [ Equation 1 ]$$

By transforming Equation 1 into the same form as Equation 2, the transfer function (gain) is represented by Equation 3.

$$\begin{matrix}y = \frac{a}{x - p} + q & [ Equation 2 ] \\ Gain = \frac{- {gmR}^{2} ( {gm}^{4} {R}^{4} + 2 {gm}^{2} {R}^{2} + 1 )}{{R}_{FB} + 2 R + {gm}^{2} {R}^{3}} + {gm}^{3} {R}^{3} & [ Equation 3 ]\end{matrix}$$

Equation 3 is represented by a rectangular hyperbola with asymptotes R_{FB}=−(2R+gm² R³) and Gain=gm³ R³, as shown in FIG. 6. The gain increases as the resistance R_{FB} of the internal feedback resistor 112 increases, according to the rectangular hyperbola shown in FIG. 6. Also, the gain decreases as the resistance R_{FB} of the internal feedback resistor 112 decreases.

As a result, a desired gain can be obtained by adjusting the resistance R_{FB} of the internal feedback resistor 112.

Therefore, the open loop gain of the operational amplifier 105 can be adjusted with the multi-stage amplifier composed of the first transistor 108, the second transistor 110 and the third transistor 111 shown in FIG. 1. When it is made possible to adjust the open loop gain of the operational amplifier 105, the total gain of the operational amplifier 105 shown in FIG. 1 can be reduced, eliminating the worry of oscillation at the signal frequency f₃, as shown in FIG. 4.

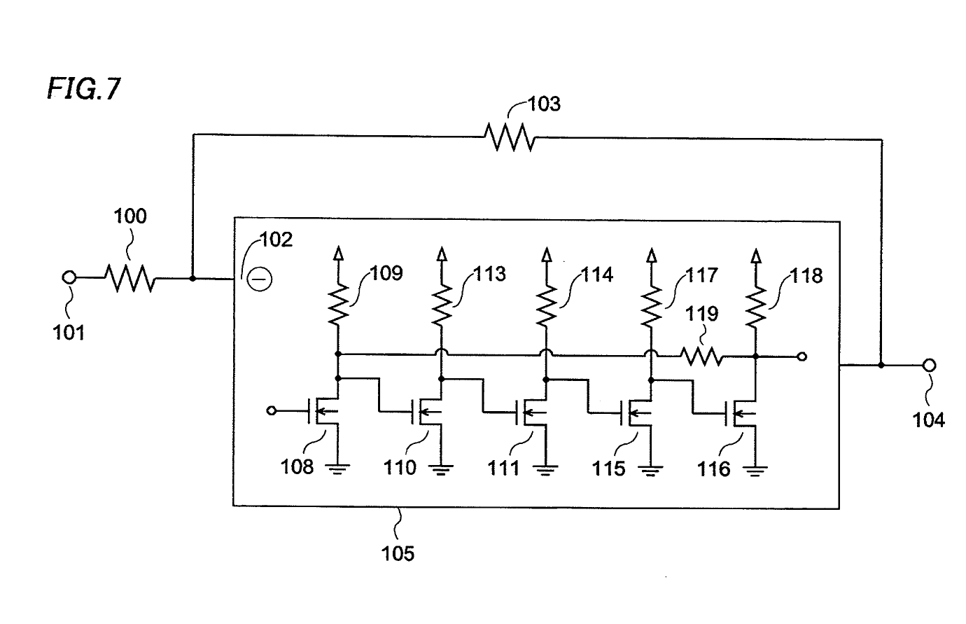

A second embodiment of this invention is described in detail, referring to FIG. 7. FIG. 7 shows an inverting amplifier according to the second embodiment.

FIG. 7 shows a first resistor 100 connected between an input terminal 101 and an inverting input terminal 102, a second resistor 103 connected between an output terminal 104 and the inverting input terminal 102, an operational amplifier 105, a first transistor 108 that has a gate to which an input signal from the inverting input terminal 102 is applied, a source which is grounded and a drain to which a resistor 109 is connected and amplifies the input signal, a second transistor 110 that amplifies an output signal of the first transistor 108, a third transistor 111 that amplifies an output signal of the second transistor 110, a fourth transistor 115 that amplifies an output signal of the third transistor 111, a fifth transistor 116 that amplifies an output signal of the fourth transistor 115 and an internal feedback resistor 119 that feeds back an output signal of the fifth transistor 116 to an output node of the first transistor 108.

Here, an open loop gain of the operational amplifier 105 itself is determined by a total gain of a multi-stage amplifier composed of the first transistor 108, the second transistor 110, the third transistor 111, the fourth transistor 115 and the fifth transistor 116. The multi-stage amplifier includes the internal feedback resistor 119 interposed between a drain of the fifth transistor 116 and the drain of the first transistor 108. The internal feedback resistor 119 serves to reduce (adjust) the total gain of the multi-stage amplifier to a desired value.

Operation of the inverting amplifier structured as described above according to the second embodiment of this invention and effects derived from it are similar to those described in the first embodiment, thus descriptions on them are omitted. A required gain can be set without inducing oscillation, since a gain of the multi-stage amplifier composed of five-stage transistors can be reduced.

An operational amplifier with small distortion and adjustable gain and without the worry of oscillation is made available with the inverting amplifiers according to the embodiments of this invention.

Also, it is made possible to set a gain best suitable for obtaining characteristics that realize the small distortion without inducing oscillation, since the gain is adjustable with the inverting amplifiers according to the embodiments of this invention.

What is claimed is:

1. An inverting amplifier comprising a multi-stage amplifier, the multi-stage amplifier comprising:
a first transistor that amplifies an input signal;
a second transistor that amplifies an output signal of the first transistor;
a third transistor that amplifies an output signal of the second transistor; and
an internal feedback resistor that feeds back an output signal of the third transistor to an output node of the first transistor.

2. An inverting amplifier comprising a multi-stage amplifier, the multi-stage amplifier comprising:
a first transistor that amplifies an input signal;
a second transistor that amplifies an output signal of the first transistor;
a third transistor that amplifies an output signal of the second transistor;
a fourth transistor that amplifies an output signal of the third transistor;
a fifth transistor that amplifies an output signal of the fourth transistor; and
an internal feedback resistor that feeds back an output signal of the fifth transistor to an output node of the first transistor.

3. An inverting amplifier comprising:
a first resistor connected between an input terminal and an inverting input terminal;
a second resistor connected between an output terminal and the inverting input terminal; and
a multi-stage amplifier comprising a first transistor that amplifies an input signal from the inverting input terminal, a second transistor that amplifies an output signal of the first transistor, a third transistor that amplifies an output signal of the second transistor and an internal feedback resistor that feeds back an output signal of the third transistor to an output node of the first transistor.

4. The inverting amplifier of claim 1, further comprising a resistor connected with a drain of each of the first, second and third transistors, wherein a source of each of the first, second and third transistors is connected to a ground in terms of alternating current.

5. The inverting amplifier of claim 2, further comprising a resistor connected with a drain of each of the first, second, third, fourth and fifth transistors, wherein a source of each of the first, second, third, fourth and fifth transistors is connected to a ground in terms of alternating current.
